(19) United States
(12) Patent Application Publication
(10) Pub. No.: US 2004/0038517 A1
(43) Pub. Date: Feb. 26, 2004

(54) Methods of forming cobalt silicide contact structures including sidewall spacers for electrical isolation and contact structures formed thereby

(76) Inventors: Sang-Bum Kang, Seoul (KR); Kwang-Jin Moon, Yongin-si (KR); Seung-Gil Yang, Yongin-si (KR); Hee-Sook Park, Seoul (KR)

Correspondence Address: MYERS BIGEL SIBLEY & SAJOVEC, PO BOX 37428, RALEIGH, NC, 27627, US

(21) Appl. No.: 10/609,983

(22) Filed: Jun. 30, 2003

(30) Foreign Application Priority Data
Aug. 20, 2002 (KR) 2002-49131

(51) Int. Cl. H01L 21/4763

(52) U.S. Cl. 438/630; 438/639

(57) ABSTRACT

A contact structure is formed by forming an interlayer dielectric on a substrate having a semiconductive region. A contact hole is formed in the interlayer dielectric to expose the semiconductive region. A conductive structure is formed adjacent to the contact hole. Spacers are formed on inner sidewalls of the contact hole. A cobalt silicide layer is formed at a bottom of the contact hole. The spacers are configured to electrically isolate the cobalt silicide layer from the conductive structure. A conductive layer is formed on the cobalt silicide layer in the contact hole.

### RELATED APPLICATION

This application claims the benefit of Korean Patent Application No. 2002-49131, filed Aug. 20, 2002, the disclosure of which is hereby incorporated herein by reference.

### FIELD OF THE INVENTION

The present invention relates generally to methods of forming integrated circuit devices and integrated circuit devices formed thereby and, more particularly, to methods of forming contact structures and contact structures formed thereby.

### BACKGROUND OF THE INVENTION

A conventional method of fabricating a contact structure for a semiconductor device includes stacking an interlayer dielectric on a silicon substrate and forming a contact hole exposing the substrate through the interlayer dielectric. A metallic silicide layer is typically formed on the exposed substrate below the contact hole to reduce a contact resistance. This may be done by depositing a metal layer on the exposed silicon substrate below the contact hole. The resulting structure may be thermally treated to cause a chemical reaction between the silicon substrate and metal. As a result, the metallic silicide layer is formed. Thereafter, the contact hole where the metallic silicide layer is formed on a bottom thereof is filled with a conductive layer to form the contact structure. In some conventional contact structures, the metallic silicide layer may comprise titanium silicide (TiSi₂).

Unfortunately, titanium silicide may agglomerate in subsequent thermal processing treatments. This may result in increased contact resistance and/or leakage current. When titanium siilcide is doped with boron (B), the boron may react with the titanium silicide during subsequent thermal processing treatments. This may also increase contact resistance.

In other conventional contact structures, cobalt silicide (CoSi₂), which has generally good thermal stability as compared to titanium silicide, may be used as the sililcide layer. A solubility of cobalt silicide with respect to boron, phosphorus (P), and arsenic (AS) is lower than that of titanium silicide. Also, because cobalt silicide has very little reactivity with respect to boron, it is possible to obtain a lower contact resistance than with titanium silicide.

When a silicide layer is made of cobalt, however, an effective contact size of a bottom of the contact hole may increase. This is because cobalt silicide expands when the cobalt reacts with the silicon comprising the substrate to form cobalt silicide. The volume of cobalt silicide is approximately 3.5 times more than that of a deposited cobalt layer. Also, the cobalt silicide may expand to the side of the contact hole.

FIG. 1 is a graph that shows the effective contact sizes for titanium and cobalt silicide layers in a conventional contact structure. As shown in FIG. 1, the effective contact size for cobalt silicide is approximately 0.02-0.05 μm greater than that for titanium silicide.

If cobalt silicide is formed below the contact hole, however, the effective contact size may increase, which reduces the contact resistance. Thus, an increase in the effective contact size is generally advantageous in cases in which the design rule is not tight. If the design rule is reduced, however, the increase in the effective contact size may cause a short-circuit with an adjacent conductive layer, e.g., a gate electrode.

### SUMMARY OF THE INVENTION

According to some embodiments of the present invention, a contact structure is formed by forming an interlayer dielectric on a substrate having a semiconductive region. A contact hole is formed in the interlayer dielectric to expose the semiconductive region. A conductive structure is formed adjacent to the contact hole. Spacers are formed on inner sidewalls of the contact hole. A cobalt silicide layer is formed at a bottom of the contact hole. The spacers are configured to electrically isolate the cobalt silicide layer from the conductive structure. A conductive layer is formed on the cobalt silicide layer in the contact hole.

In other embodiments, the spacers comprise at least one of silicon oxide, silicon nitride, titanium nitride, tantalum nitride and boron nitride.

In still other embodiments, each of the spacers has a respective thickness of about 100-1000 Å.

In further embodiments, the cobalt silicide layer is formed by forming a cobalt layer on the exposed semiconductiv region at the bottom of the contact hole, on sidewalls of the spacers, and on the interlayer dielectric. A barrier layer is formed on the cobalt layer and the cobalt layer reacts with the substrate to form cobalt silicide while the barrier layer is formed.

In still further embodiments, the cobalt layer and the barrier layer are formed in-situ in the same processing apparatus.

In still further embodiments, the barrier layer comprises at least one of titanium nitride (TiN) and titanium/titanium nitride (Ti/TiN).

In other embodiments, the barrier layer is formed on the cobalt layer via chemical vapor deposition at a temperature of about 680-700° C.

In still other embodiments, the cobalt silicide layer is formed at the bottom of the contact hole by forming a cobalt layer on the exposed semiconductiv region at the bottom of the contact hole, on sidewalls of the spacers, and on the interlayer dielectric. The cobalt layer is thermally treated to convert a first portion of the cobalt layer that is in contact with the semiconductiv region into a cobalt silicide layer. A second portion of the cobalt layer is removed to expose the cobalt silicide at the bottom of the contact hole.

In still other embodiments, a barrier layer is formed on the cobalt silicide layer, on the sidewalls of the spacers, and on the interlayer dielectric. The barrier layer may comprise at least one of titanium nitride (TiN) and titanium/titanium nitride (Ti/TiN).

In further embodiments, the cobalt silicide layer is formed at the bottom of the contact hole by sequentially forming a cobalt layer and a capping layer on the exposed semiconductiv region at the bottom of the contact hole, on sidewalls of the spacers, and on the interlayer dielectric. The cobalt layer is thermally treated to convert a first portion of the cobalt layer that is in contact with the semiconductiv region into a cobalt monosilicide layer. A second portion of the cobalt layer and the capping layer is removed to expose the cobalt monosilicide layer at the bottom of the contact hole. The cobalt monosilicide layer is thermally treated to form a cobalt silicide layer.

Although the present invention has been described above primarily with respect to method embodiments of forming contact structures, it will be understood that the present invention may also be embodied as integrated circuit contact structures.

### BRIEF DESCRIPTION OF THE DRAWINGS

Other features of the present invention will be more readily understood from the following detailed description of specific embodiments thereof when read in conjunction with the accompanying drawings, in which:

FIG. 1 is a graph that shows the effective contact sizes for titanium and cobalt silicide layers in a conventional contact structure;

FIGS. 2 through 7 are cross-sectional views that illustrate methods of fabricating a contact structure in accordance with some embodiments of the present invention; and

FIGS. 8 through 12 are cross-sectional views that illustrate methods of fabricating a contact structure according to other embodiments of the present invention.

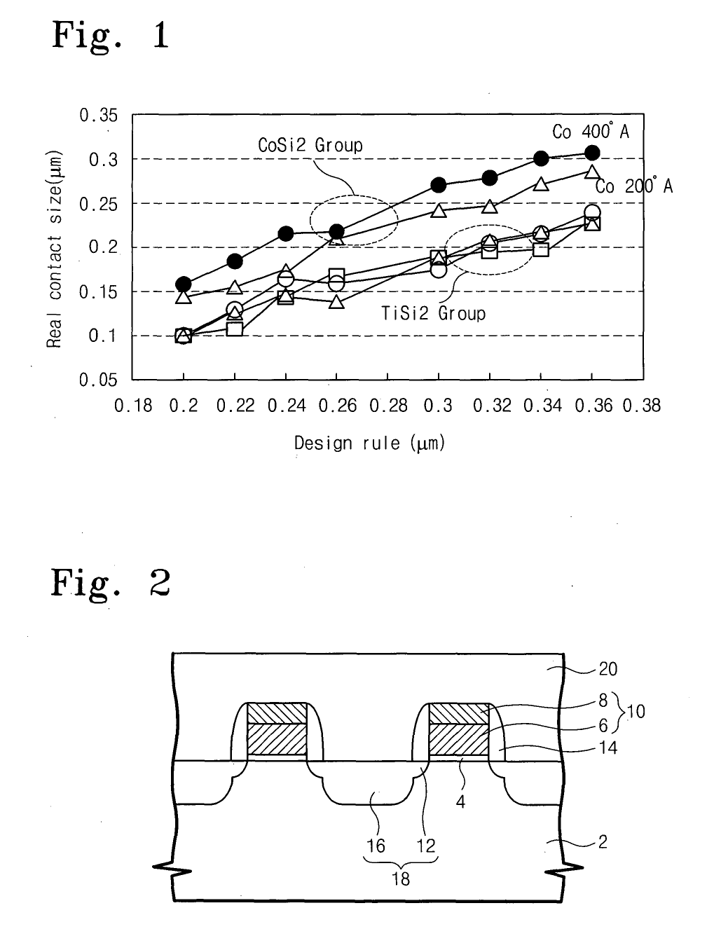

### DETAILED DESCRIPTION OF PREFERRED EMBODIMENTS

While the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention as defined by the claims. Like numbers refer to like elements throughout the description of the figures. In the figures, the dimensions of layers and regions are exaggerated for clarity. It will also be understood that when an element, such as a layer, region, or substrate, is referred to as being “on” another element, it can be directly on the other element or intervening elements may be present. In contrast, when an element, such as a layer, region, or substrate, is referred to as being “directly on” another element, there are no intervening elements present.

FIGS. 2 through 7 are cross-sectional views that illustrate methods of fabricating a contact structure in accordance with some embodiments of the present invention. Referring now to FIG. 2, a device isolation region (not shown) is formed on a substrate 2 to define an active region. A gate insulating layer 4 and a gate conductive layer 10 are sequentially stacked on the substrate 2 where the active region is defined. The gate conductive layer 10 may comprise a polysilicon layer 6 and a silicide layer 8. The gate conductive layer 10 and the gate insulating layer 4 are patterned to form a gate stack. A lightly doped region 12 is formed using the gate stack as an ion implantation mask. A gate spacer insulating layer is formed on a surface of the substrate 2 where the gate stack is formed. The gate spacer insulating layer is anisotropically etched to form a gate spacer 14 on sidewalls of the gate stack. Next, a heavily doped region 16 is formed using the gate stack and the gate spacer 14 as an ion implantation mask. The lightly and heavily doped regions 12 and 16 constitute a source/drain region 18. An interlayer dielectric 20 is formed on the surface of the substrate 2 and gate stack and is planarized.

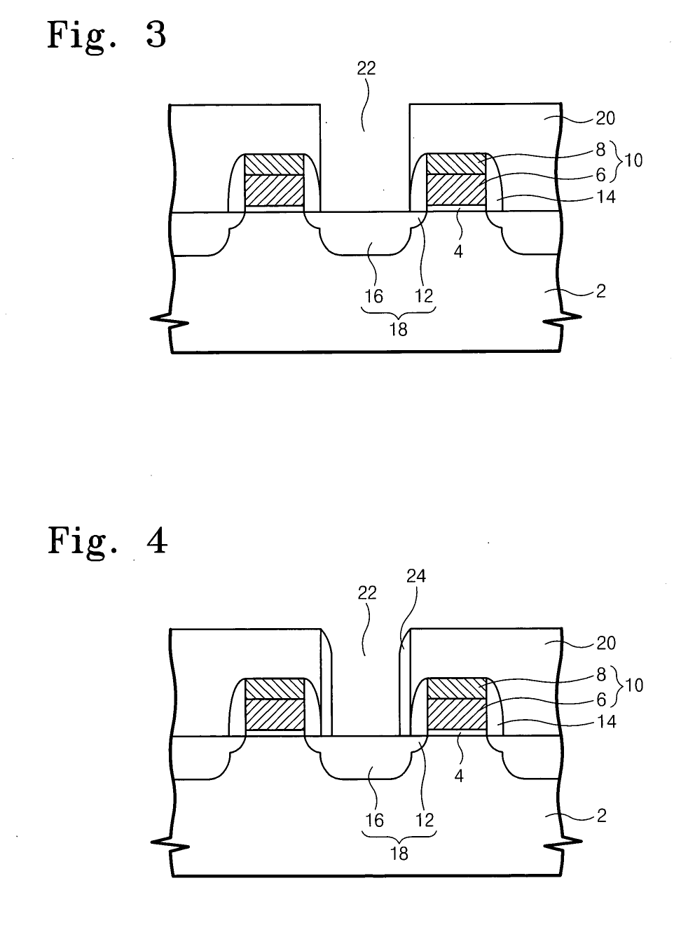

Referring now to FIG. 3, a photolithographic etching process is performed on the interlayer dielectric 20 to form a contact hole 22 exposing the doped regions 18. Referring now to FIG. 4, a spacer insulating layer is conformally stacked at a bottom and a sidewall of the contact hole 22 and on the interlayer dielectric 20. The spacer insulating layer is anisotropically dry-etched to form spacers 24 on inner sidewalls of the contact hole. The spacer insulating layer may comprise silicon nitride (SiN), silicon oxide (SiO₂), boron nitride (BN), titanium nitride (TiN) and/or tantalum nitride (TaN). The spacer insulating layer may have a thickness of about 100-1000 Å.

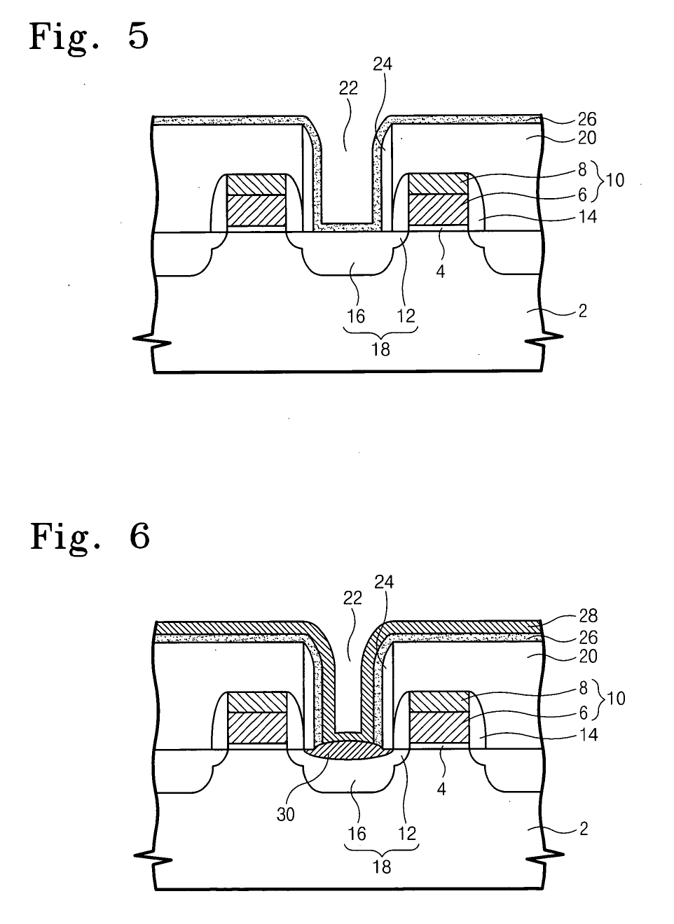

Referring now to FIG. 5, a cobalt layer 26 is formed on the spacers 24 on a bottom of the contact hole 22 and on the interlayer dielectric 20. The cobalt layer 26 may be formed using atomic layer deposition (ALD), chemical vapor deposition (CVD), or physical vapor deposition (PVD). If the PVD is combined with doping, then, to enhance morphology of the cobalt layer, the processing temperature may be increased up to 500° C. following deposition of the cobalt layer.

Referring now to FIG. 6, a barrier layer 28, which may comprise titanium nitride (TiN), is formed on the cobalt layer 26. In other embodiments, a titanium (Ti) layer may be formed before forming the titanium nitride (TiN) layer. In some embodiments, the cobalt layer 26 and the barrier layer 28 are formed in-situ in the same apparatus. A titanium (Ti) layer, which may comprise the barrier layer 28, may be formed using CVD at a temperature of about 630° C. The titanium (Ti) layer may have a thickness of about 10-500 Å. The titanium nitride (TiN) layer may be formed using CVD at a temperature of about 680-700° C. The titanium nitride (TiN) layer may have a thickness of about 100 Å or greater.

When the barrier layer 28 is formed, the cobalt layer 26 connected to the silicon substrate at a bottom of the contact hole 22 reacts with the silicon substrate to form cobalt silicide 30. As illustrated, the volume of cobalt silicide 30 expands to increase the effective contact size. The spacers 24 formed on the inner sidewalls of the contact hole 22 may suppress the volume expansion of cobalt silicide 30 to prevent a short-circuit of the gate electrode 10 at one or both sides of the contact hole.

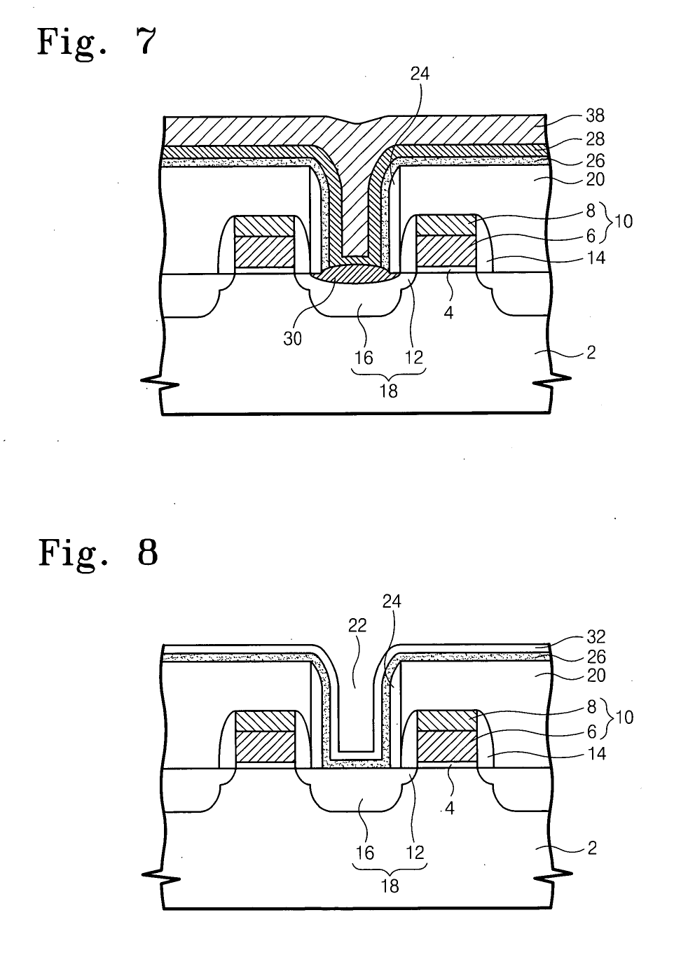

Referring to FIG. 7, a conductive layer 38 is formed on the barrier layer 26 to fill the contact hole 22 to complete the contact structure. The conductive layer 38 may comprise tungsten (W), aluminum (Al), titanium nitride (TiN) and/or tantalum nitride (TaN). The conductive layer 38 may be planarized by an etch back and/or CMP process until the interlayer dielectric is exposed thereby forming a contact plug.

FIGS. 8 through 12 are cross-sectional views that illustrate methods of fabricating a contact structure according to other embodiments of the present invention. Referring now to FIG. 8, the cobalt layer 26 is deposited on a bottom of the contact hole 22, on the spacers 24 formed on inner sidewalls of the contact hole 22, and on the interlayer dielectric 20. A capping layer 32, which may comprise titanium nitride (TiN), may be formed on the cobalt layer 26.

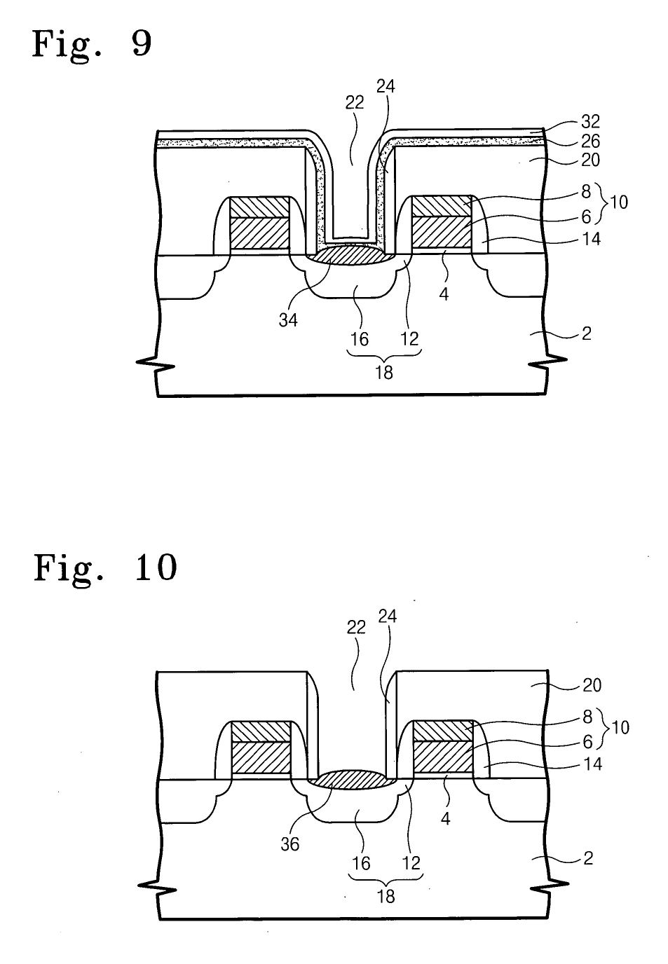

Referring now to FIG. 9, after thermally treating the resulting structure, the cobalt layer 26 disposed at the bottom of the contact hole 22 reacts with the silicon substrate to form cobalt monosilicide (CoSi) 34. As discussed above, the volume of cobalt monosilicide 34 expands to increase an effective contact size. The spacers 24 formed on the inner sidewalls of the contact hole 22 may suppress the volume expansion of cobalt monosilicide 34 to prevent a short-circuit of the gate electrode 10 at one or both sides of the contact hole.

Referring now to FIG. 10, the capping layer 32 and the non-reacting cobalt layer 26 are removed to expose cobalt monosilicide formed at the bottom of the contact hole 22. The surface of the resulting structure is thermally treated to convert cobalt monosilicide into a cobalt silicide layer 36. An oxide layer may be formed on cobalt silicide 36 during the thermal process, which may be removed by a cleaning process.

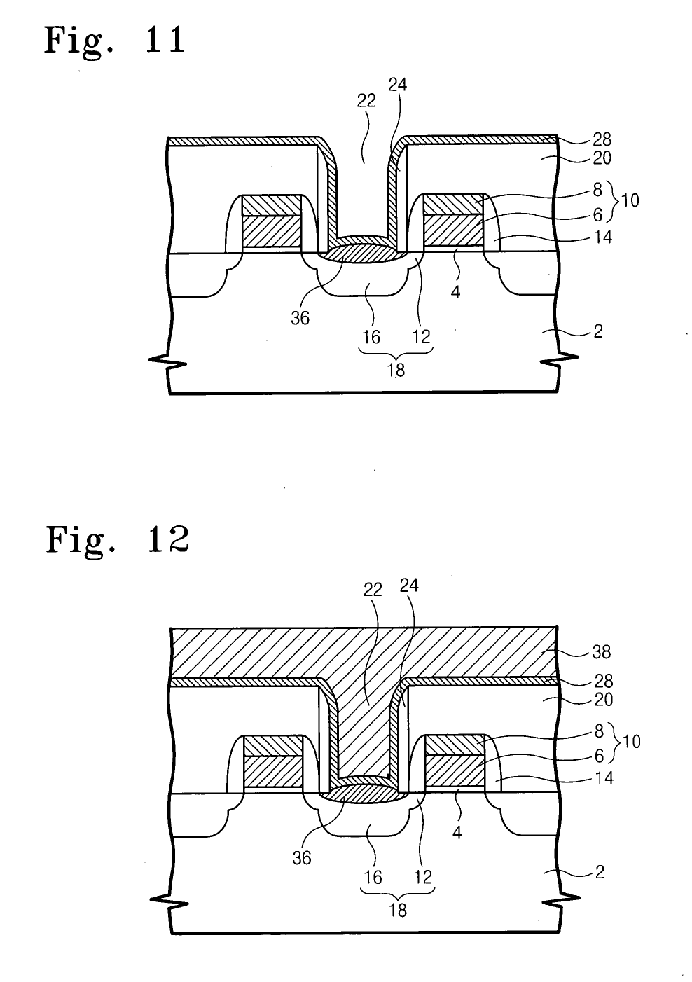

Referring now to FIG. 11, the barrier layer 28 is formed in the contact hole 22 having cobalt silicide 36 and on the interlayer dielectric 20. The barrier layer 28 may comprise titanium nitride (TiN) and, in other embodiments, a titanium (Ti) layer may be formed before forming the titanium nitride (TiN) layer. In some embodiments, the cobalt layer 26 and the barrier layer 28 are formed in-situ in the same apparatus.

Referring now to FIG. 12, the conductive layer 38 is formed on the barrier layer 28 to fill the contact hole 22 and to complete the contact structure. The conductive layer 38 may comprise tungsten (W), aluminum (Al), titanium nitride (TiN) and/or tantalum nitride (TaN). The conductive layer 38 may be planarized by an etch back and/or CMP process until the interlayer dielectric is exposed thereby forming a contact plug.

Thus, according to some embodiments of the present invention, cobalt and capping layers are sequentially formed at the bottom of a contact hole. The cobalt layer is converted into cobalt monosilicide through an annealing/thermal treatment process. Thereafter, the capping layer and the non-reacting cobalt layer are removed and the structure is thermally treated so as to convert the monosilicide layer (CoSi) into cobalt silicide (CoSi₂). That is, two thermal treatments are performed to form cobalt silicide (CoSi₂). In other embodiments, a cobalt layer is formed at the bottom of a contact hole. The cobalt layer is thermally treated to form cobalt silicide (CoSi₂). Thereafter, the non-reacting cobalt layer is removed. In this case, only one thermal treatment is performed.

In some embodiments of the present invention, a contact hole is formed in an interlayer dielectric and spacers are formed on inner sidewalls of the contact hole. Advantageously, the spacers may reduce the likelihood of a short-circuit forming between, for example, an ohmic contact comprising cobalt-silicide and an adjacent conductive structure.

In concluding the detailed description, it should be noted that many variations and modifications can be made to the preferred embodiments without substantially departing from the principles of the present invention. All such variations and modifications are intended to be included herein within the scope of the present invention, as set forth in the following claims.

That which is claimed:

1. A method of fabricating a contact structure, comprising:
forming an interlayer dielectric on a substrate having a semiconductive region;
forming a contact hole in the interlayer dielectric to expose the semiconductive region;
forming spacers on inner sidewalls of the contact hole;
forming a cobalt silicide layer at a bottom of the contact hole; and
forming a conductive layer to fill the contact hole.

2. The method of claim 1, wherein the spacers comprise at least one of silicon oxide, silicon nitride, titanium nitride, tantalum nitride and boron nitride.

3. The method of claim 1, wherein each of the spacers has a respective thickness of about 100-1000 Å.

4. The method of claim 1, wherein forming the cobalt silicide layer at the bottom of the contact hole comprises:
forming a cobalt layer on the exposed semiconductive region at the bottom of the contact hole, on sidewalls of the spacers, and on the interlayer dielectric; and
forming a barrier layer on the cobalt layer;
wherein the cobalt layer reacts with the substrate to form the cobalt silicide while the barrier layer is formed, and wherein the conductive layer is formed on the barrier layer.

5. The method of claim 4, wherein the cobalt layer and the barrier layer are formed in-situ in a same processing apparatus.

6. The method of claim 4, wherein the barrier layer comprises at least one of titanium nitride (TiN) and titanium/titanium nitride (Ti/TiN).

7. The method of claim 4, wherein forming the barrier layer on the cobalt layer comprises:
forming the barrier layer on the cobalt layer using chemical vapor deposition at a temperature of about 680-700° C.

8. The method of claim 1, wherein forming the cobalt silicide layer at the bottom of the contact hole comprises:
forming a cobalt layer on the exposed semiconductiv region at the bottom of the contact hole, on sidewalls of the spacers, and on the interlayer dielectric;
thermally treating the cobalt layer to convert a first portion of the cobalt layer that is in contact with the semiconductiv region into a cobalt silicide layer; and
removing a second portion of the cobalt layer to expose the cobalt silicide at the bottom of the contact hole.

9. The method of claim 8, further comprising:
forming a barrier layer on the cobalt silicide layer, on the sidewalls of the spacers, and on the interlayer dielectric.

10. The method of claim 8, wherein the barrier layer comprises at least one of titanium nitride (TiN) and titanium/titanium nitride (Ti/TiN).

11. The method of claim 1, wherein forming the cobalt silicide layer at the bottom of the contact hole comprises:
sequentially forming a cobalt layer and a capping layer on the exposed semiconductiv region at the bottom of the contact hole, on sidewalls of the spacers, and on the interlayer dielectric;
thermally treating the cobalt layer to convert a first portion of the cobalt layer that is in contact with the semiconductiv region into a cobalt monosilicide layer;
removing a second portion of the cobalt layer and the capping layer to expose the cobalt monosilicide layer at the bottom of the contact hole; and
thermally treating the cobalt monosilicide layer to form a cobalt silicide layer.

12. The method of claim 11, further comprising:
forming a barrier layer on the cobalt silicide layer.

13. The method of claim 12, wherein the barrier layer comprises at least one of titanium nitride (TiN) or titanium/titanium nitride (Ti/TiN).

14. The method of claim 13, wherein forming the conductive layer comprises:
forming the conductive layer on the barrier layer.

15. The method of claim 1, further comprising:
planarizing the conductive layer until the interlayer dielectric is exposed.

16. A contact structure comprising:
an interlayer dielectric disposed on a substrate and having a contact hole formed therein that exposes a semiconductiv region of the substrate;
a cobalt silicide layer that is disposed at a bottom of the contact hole;
a pair of spacers that are respectively disposed on opposing sidewalls of the contact hole; and
a conductive layer that is disposed on the cobalt silicide layer in the contact hole.

17. The contact structure of claim 16, wherein a barrier layer is disposed between the spacers and the conductive layer.

18. The contact structure of claim 17, wherein the barrier layer comprises at least one of titanium nitride (TiN) and titanium/titanium nitride (Ti/TiN).

19. The contact structure as claimed in claim 16, wherein the spacers comprise at least one of silicon oxide, silicon nitride, titanium nitride, tantalum nitride and boron nitride.
